(19) United States
(12) Patent Application Publication
(10) Pub. No.: US 2014/0311559 A1
(43) Pub. Date: Oct. 23, 2014

(54) THE DUAL SURFACE SUNLIGHT TRAPPING PHOTOVOLTAIC SOLAR LEAF MODULE

(71) Applicants: Vinh Minh Glisttenmeer Lam, Hayward, CA (US); Ethan Lam, Fremont, CA (US); Megan Lam, Fremont, CA (US); Victor Lam, Fremont, CA (US)

(72) Inventors: Vinh Minh Glisttenmeer Lam, Hayward, CA (US); Ethan Lam, Fremont, CA (US); Megan Lam, Fremont, CA (US); Victor Lam, Fremont, CA (US)

(21) Appl. No.: 13/865,999

(22) Filed: Apr. 18, 2013

(51) Int. Cl. H01L 31/048

(52) U.S. Cl. CPC H01L 31/048
USPC 136/256; 29/428; 29/825

(57) ABSTRACT

We describe an invention, the Photovoltaic Solar Leaf Module, comprising of an active photovoltaic (PV) thin film layer being sandwiched and laminated by two sheets of light trapping surface textured polymer, which also form a durable, light weight and flexible protective casing around the active PV thin film layer, which is capable of absorbing sunlight on its front and back surfaces. A method of mounting our PV leaf module is described whereby many PV solar leaf modules are mounted in an array onto many horizontal rods, which are then mounted along a vertical pole supported by a base, which is attached to the ground surface. Another method of mounting the PV leaf module is also described whereby many PV solar leaf modules are electrically and mechanically attached to a long flexible electrical cord, forming an array of many PV solar leaf modules along the length of the flexible electrical cord.

### FIELD OF THE INVENTION

This invention relates to the design of a photovoltaic solar cell module comprising of an active photovoltaic thin film layer that is sandwiched between two thin sheets of light trapping surface textured transparent polymer, resulting in a flexible, durable and lightweight solar PV module capable of absorbing and trapping sunlight on both surfaces of the module.

### BACKGROUND OF THE INVENTION

### Description of the Prior Art

### References Cited

| patent or Application | | | |
|---|---|---|---|
| No. | Date | Inventor | Field |
| US20100243051 | Nov. 5, 2008 | Slager | 136/257 |
| US20110005593 | Mar. 4, 2009 | Slager | 136/256 |
| US20110114176 | Jun. 17, 2009 | Slager | 136/257 |
| US20100126570 | Oct. 23, 2009 | Kizilyalli et al | 136/255 |
| US20120031489 | Apr. 8, 2010 | Slager | 136/259 |
| US20120024355 | Apr. 8, 2010 | Slager | 136/251 |
| 8,003,492 | Aug. 23, 2011 | Gmitter et al | 438/458 |

There is a need in our world for clean energy. Solar energy is the cleanest and it is freely available. However, adopting photovoltaic (PV) solar energy technology on a wide scale is limited by many important factors. These factors include the cost of manufacturing the active PV layer and the cost of all other components necessary to encapsulate and mount the active PV layer, which is called the balance of system. The cost of the active PV layer can be reduced if the active PV layer can be made very thin. The cost of the balance of system components can be reduced by redesigning the module to minimize the number of components necessary to support, encapsulate, and mount the active PV thin film layer. The prior art uses mono and poly-crystalline silicon photovoltaic solar cell encapsulated in glass and aluminum frame, which lead to a very heavy, bulky, fragile and expensive panel. In addition, the prior art's solar PV panel requires many components in its balance of system. The Si active PV layer is thick, inflexible, brittle, and costly to manufacture. The enormous number of components in its balance of system further increases the cost of producing these solar panel modules from the prior art. When there are too many components in a solar panel, the cost of labor also increases in assembling components together and mounting the solar panel.

Recognizing the needs to reduce these costs, the solar PV industry is moving toward newer design of solar PV module as well as newer technique of manufacturing the individual solar PV active layer in order to reduce cost. For example, the company Uni-Solar has produced flexible self adhesive solar PV module that can be rolled onto and adhered to rooftops without using conventional mounting components, greatly reducing the number of components in its balance of system. It is possible to improve on the design of the module in order to further reduce the number of components in order to reduce cost. Our invention will describe how this can be done.

The prior art is also moving toward more efficient method of producing the active layers of the PV cell. Si mono and poly-crystalline solar cell are thick, bulky, and brittle. Recently, progress has been made in manufacturing thin film solar PV cell that are very thin, lightweight, and flexible, resulting in lower cost and greater durability. For example, Alta Devices Inc. has produced an active PV layer, comprising of a very thin film of GaAs that is flexible with a thickness of 500 nm or less. This is described in their patent application, US20100126570. In fact, Alta Devices Inc. has produced an active PV layer of Gallium Arsenide (GaAs) thin film solar cell with thickness of 100 nm. At this thickness, the active PV thin film solar cell becomes very flexible, efficient, and consumes very little material in its production. Their patent discloses an active PV GaAs thin film layer solar cell with a silver coating on the back surface and two anti-reflection coatings on the front surface of the GaAs active PV thin film layer. The antireflection coatings increase the amount of sunlight absorbed by the active PV layer. The silver coating on the back surface functions as a mirror to reflect any sunlight loss through transmission across the active PV layer. This prior art's GaAs thin film solar cell provides a tremendous improvement in terms of efficiency, 28%, and reduction in cost with a thickness of 500 nm or less. The way to produce such thin film is described in another patent of Alta Devices Inc., U.S. Pat. No. 8,003,492, which describes how epitaxial lift off can achieve a thickness of 500 nm or less, resulting in substantial saving in the cost of the material. Despite this tremendous improvement in efficiency and cost saving for a single junction GaAs thin film PV solar cell, there is room for further improvement. Our invention will describe how such improvement can be achieved.

The prior art has also made improvement in channeling sunlight onto the active PV thin film layer. The most common method is to provide an anti-reflection coating on the surface of solar PV cell. A more recent advance in the prior art is to trap sunlight using textured surface polymer coating on the surface of the active PV layer. This is described in a patent application, US20120024355, owned by Solar Excel Inc. Light rays are redirected back onto the active PV thin film layer by the textured surface. This mechanism of trapping light is described in another patent application, US20100243051. The geometry of the textured surface is described in patent application, US20110005593. The method of forming such textured surface polymer is described in patent application, US20120031489. The above patent applications are all owned by Solar Excel Inc. In fact, Solar Excel is currently commercially selling light trapping surface textured polymer sheets for solar PV panel. Our invention will utilize two sheets of light trapping surface textured polymer to laminate an active PV thin film layer of GaAs to produce a new type of solar cell module that can absorb and trap sunlight on both surfaces.

### SUMMARY OF THE INVENTION

Our invention, the photovoltaic (PV) solar leaf module comprises of a very thin GaAs thin film PV layer sandwiched between two surface textured light trapping polymer sheets. Preferably, the thickness of the GaAs active PV layer is between 100 nm to 200 nm. A surface textured light trapping polymer sheet is placed in optical contact on the front surface of the GaAs active PV thin film layer. Another surface textured light trapping polymer sheet is placed on the back surface of the GaAs active PV thin film layer. Pressure and heat can be applied to compress the two surface textured polymer sheets around the GaAs active PV thin film layer under vacuum, which will force the polymer sheets into optical contact with the GaAs active PV thin film layer surfaces. Under heat and pressure, the two polymer sheets will also laminate together around the edges to form a structurally strong protective covering for the GaAs PV active thin film layer. The main advantage of our invention, the PV solar leaf module allows for sunlight to be absorbed on both surfaces of the device, which is an improvement over the prior art, which produces solar PV cell that can only absorb sunlight on one single surface. Furthermore, our invention, the PV solar leaf module is lightweight, flexible, thin and flexible, which reduces the number of components in the balance of systems. Thus, our invention, the photovoltaic solar leaf module provide major improvements over the prior art. We also describe a method of mounting our PV solar leaf module whereby many PV solar leaf modules are mounted in an array onto many horizontal rods, which are then mounted along a vertical pole supported by a base, which is attached to the ground surface. Another method of mounting the solar leaf module is also described whereby many PV solar leaf modules are electrically and mechanically attached to a long flexible electrical cord, forming an array of many PV solar leaf modules along the length of the long flexible electrical cord. The advantages of these methods will be described in detail below.

### BRIEF DESCRIPTION OF FIGURES

FIG. 1 depicts a flexible Photovoltaic (PV) solar leaf module in isometric view.

FIG. 2 depicts how the active PV thin film layer is sandwiched between two textured surface light trapping polymer sheets.

FIG. 3A depicts a front view of the PV solar leaf module.

FIG. 3B depicts a cross section view of the PV solar leaf module.

FIG. 3C depicts another cross section view of the PV leaf.

FIG. 4A depicts the front view of how the PV solar leaf modules are arrayed around a rod.

FIG. 4B depicts an isometric view of how the PV solar leaf modules are arrayed around a rod.

FIG. 5A depicts an isometric view of how the PV solar leaf modules are mounted vertically on a pole.

FIG. 5B depicts a front view of how the PV solar leaf modules are mounted vertically on a pole.

FIG. 5C depicts a top view of how the PV solar leaf modules are mounted vertically on a pole.

FIGS. 6A and 6B shows two isometric views of how the PV solar leaf modules can be mounted along a long, flexible and durable electrical cord.

### DETAILED DESCRIPTION OF THE INVENTION

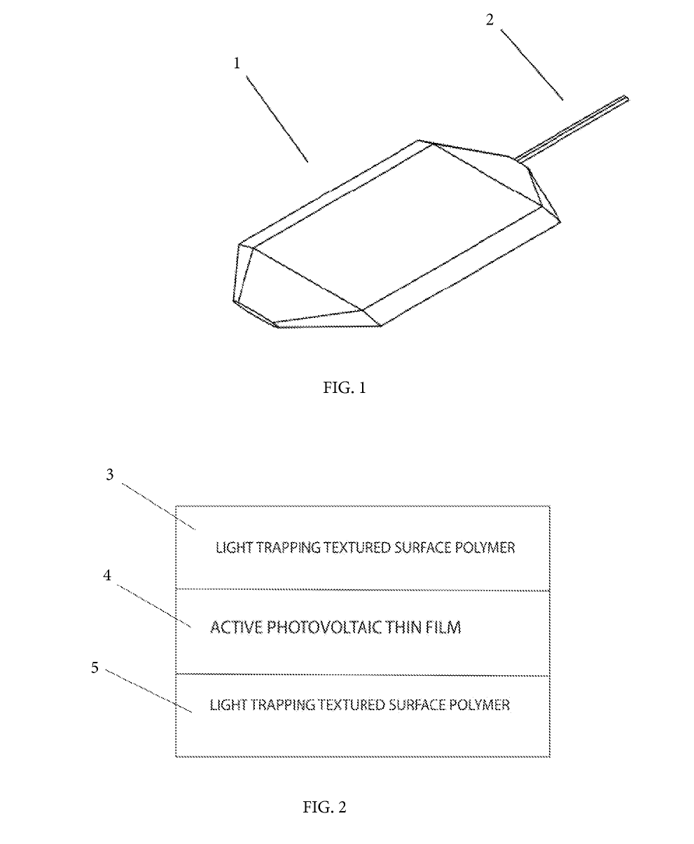

Our invention incorporates two existing technologies in the prior art, the GaAs thin film solar PV cell, with a thickness of 500 nm or less and the light trapping surfaced textured polymer sheet. The active PV thin film layer of GaAs has been produced in the prior art by Alta Device Inc in Sunnyvale, Calif. The textured surface light trapping polymer sheet has been produced by Solar Excel Inc located in the Netherland. Alta Device Inc has a website at http://www.altadevices.com. Solar Excel Inc has a website at http://www.solarexcel.nl. Furthermore, the patents of these prior art are listed in the background section above. Their patents explain in detail how the GaAs thin film is created as well as how the light trapping textured polymer is made from resin. Their patents also described how the surface textured polymer traps sunlight by using various geometries textured onto the polymer, which traps the sunlight by redirecting the sunlight onto the active PV thin film layer. These two prior art technologies are described in great detail in their patents, and the readers are referred to these patents listed in the background section. Combining the prior art in a novel, non-obvious, and very useful way, we are able to create a new type of PV solar module that has never existed before, the PV solar leaf module. FIG. 1 shows an isometric view of our invention, a photovoltaic (PV) solar leaf module 1. The PV solar leaf module 1 comprises of an active thin film PV layer 4 laminated by two sheets of light trapping surface textured polymer 3 and 5 in FIG. 2. Both surfaces of this PV solar leaf module can absorb sunlight. A positive and a negative electrode terminal 2 protrude from the PV solar leaf module 1. The positive and negative electrode terminals are shown tightly wound and bound together, which we will refer to as an electrical cord 2 from now on.

The active photovoltaic (PV) thin film layer 4 is laminated between two sheets of light trapping surface textured polymer 3 and 5. The light trapping surface textured polymers 3 and 5 are in optical contact with the active PV thin film layer 4 on the front surface as well as the back surface. These two sheets of surface textured polymers 3 and 5 trapped sunlight by redirecting sunlight back onto the active thin film PV layer 4. Furthermore, these two sheets of polymer 3 and 5 also provide a air-tight and water-tight protective casing around the active PV thin film layer.

The active thin film PV layer 4 comprises of a p-doped emitter layer adjacent to an n-doped base layer, which form a pn junction. When sunlight is absorbed onto the active thin film, an electron and a hole pair is produced, with the electron diffusing to the n-doped layer and the hole diffusing to the p-doped layer, which create a voltage across the pn junction, allowing current to flow across the metallic contacts to the electrical terminal or electrical cord. On the surfaces of the active thin film PV layer 4 are laid a n-type metal contact to attract electrons and a p-type metal contact to attract holes. These metallic contacts are further connected to the electrical terminals which forms the electrical cord 2. There are many variations to the composition and structure of active thin film PV layer, and are widely available and disclosed in the prior art's literature. The above description is one example of a typical active thin film PV layer.

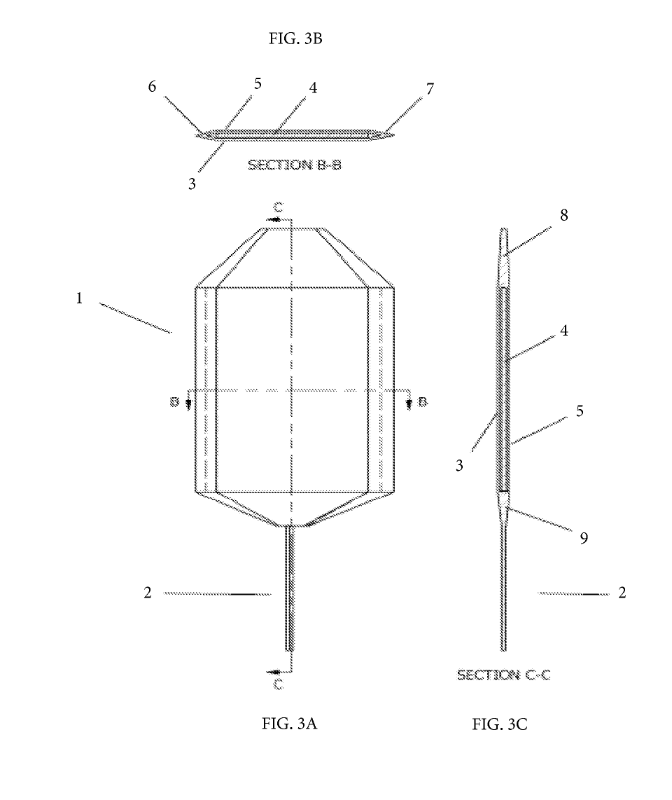

The PV solar leaf module is shown in FIG. 3A. The PV solar leaf 1 is very thin. The active thin film PV layer is 500 nm or less, while the surface textured polymer sheets are 2 mm or less. So, the thickness of the PV leaf can be 4 mm or less. By choosing a thinner light trapping polymer sheet, it is possible to make the PV leaf as thin as 2 mm. It is foreseeable that in the future, the polymer sheet can be made even thinner such that the resulting PV leaf may even be 1 mm in thickness or less. These various embodiments are conceivable to a person skilled in the art. Currently, our prefer embodiment is to utilize an active thin film PV layer with a thickness of 100 nm and light trapping surface textured polymer sheet with a thickness of 2 mm, which are currently available commercially. However, as the technology improves in making these components thinner, we intend to utilize an active PV thin film layer that is 50 nm in thickness and light trapping polymer sheets that is 0.5 mm in thickness. An ordinary person skilled in the art will be able to design a solar PV leaf module as thin as 1 mm with all the wonderful properties of being extremely light weight, very flexible and very durable in the near future.

The prior art has been able to produced an active PV thin film layer that ranges from 100 nm to 500 nm. Alta Devices Inc has made such a PV thin film layer from GaAs. By incorporating such a thin film of active PV layer into our invention, the PV solar leaf module, allows for flexibility and durability of the PV layer. At 500 nm or less, the GaAs PV layer can be very flexible, which will prevent fracture or breakage. When placed in the external environment, winds, rains, snows, and other weather conditions will not be able to damage our PV solar leaf module because it is very flexible and durable. At 500 nm or less, the PV layer can be transparent to sunlight transmission. The thinner it is, the more easily sunlight is transmitted across the PV layer. The physics of light absorption indicate that as the PV layer becomes thinner, there is less material to absorb sunlight as it is transmitted across the PV layer. Therefore, if we choose a thickness of 100 nm for the active PV thin film layer, we will see that much more sunlight will be transmitted through the PV layer. For this reason, our invention, the PV solar leaf module provides for two light trapping surface textured polymer sheets 3 and 5 to be in optical contacts on both sides of the PV active thin film layer 4 in order to redirect any transmitted light back toward the active PV layer.

In contrast, the prior art uses a silver coating for the back surface of the active PV layer. Such a silver coating acts as an inefficient mirror to reflect light back to the front surface of the PV layer. Furthermore, in using a silver coating on the back surface of the PV layer, the prior art increases the cost of production and material. The prior art also uses multiple anti-reflection coatings on the front surface of PV layer, which increase the cost of production and material. Our invention, the PV solar leaf module, avoids using anti-reflection coatings and avoids using silver coating because with light trapping polymer sheets, these anti-reflection coating and silver coating are unnecessary. The light trapping surface textured polymer sheets trap and redirect sunlight back onto the active PV layer. For this reason, our invention, the PV solar leaf module provides a major improvement to the prior art in terms of efficiency and cost of production. Again, these light trapping surface textured polymer sheets are available commercially from Solar Excel Inc in the Netherland.

Our invention, the PV solar leaf module also provides another major improvement over the prior art's solar cell module. All prior art's solar cell module can only absorb sunlight on one surface of the module. Our PV solar leaf module allows absorption of sunlight on both surfaces. By absorbing sunlight on both surfaces, our PV solar leaf module increases the amount of sunlight available for generating electricity. Since sunlight tends to reflect from surfaces such as concrete, walls, ground snow surfaces, rooftops, and other urban structures, reflected sunlight can be absorbed on both surfaces of the PV solar leaf module. As the sun traverses across the sky, both surfaces of the PV solar leaf module can absorb sunlight regardless of the position of the sun in the sky.

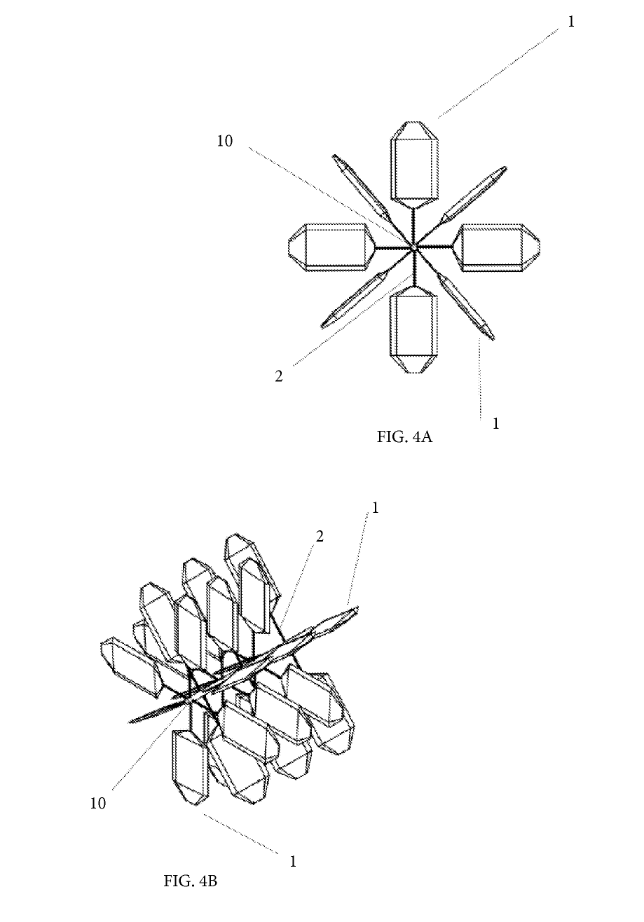

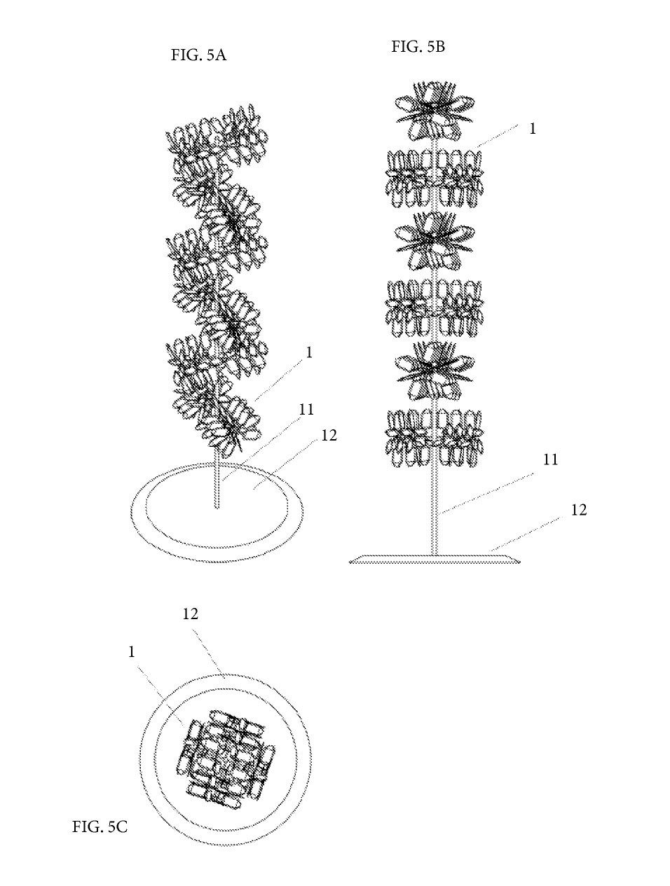

In the form and shape of a leaf, our invention, the PV solar leaf module, can be mounted onto various structures both horizontally and vertically, which provides for enormous versatility in its ability to capture sunlight under all environmental conditions in all regions of the world. Being very thin, flexible, lightweight and durable, our PV solar leaf module can be mounted on any structure, anywhere in the world in all weather condition. As an example, we describe one method of mounting an array of solar PV leaves horizontally and vertically onto a vertical pole. FIG. 4A shows how the solar PV leaves 1 are mounted in an array circularly around a rod 10. In various orientations at various angles, the solar PV leaves 1 are arrayed along the rod 10. The electrical cord 2 is connected to the rod 10. The electrical cord 2 also serves as a structural attachment for the PV solar leaf module to securely attach it to the rod 10. FIG. 4B shows an isometric view of the resulting array of solar PV leaves around the rod, which resemble a branch. These branches of solar PV leaves 1 are then mounted to a vertical pole 11 in FIG. 5A. The pole is supported by a base 12. The base 12 can be bolted to the ground, embedded into the ground, or simply placed on the ground. The branches of solar PV leaves 1 are arrayed in various orientations along the length of the vertical pole 11. The electrical wiring can be integrated into the vertical pole 11 and rod 10 by those skilled in the art. This is just one example of how our invention, the PV solar leaf module, can be mounted.

Because of the light weight of the PV solar leaf module, the supporting structures can utilize less material. In fact, there are fewer components in the balance of system to support our PV solar leaf module. Fewer components required to mount our PV solar leaf module translates into lower cost and ease of utilization, making it accessible to a wider population of people. To further decrease the cost of the components, we prefer to use widely available and inexpensive material for the structural components, such as the vertical pole 11, rod 10, and base 12 which can be made of Polyvinyl chloride polymer (PVC) or other corrosion resistant polymer. An even better structural material would be to use natural bamboo trees as starting material to construct the vertical poles 11, rods 10 and base support 12. Natural bamboo trees are structurally flexible, light weight, strong, inexpensive and widely available everywhere on Earth. Natural bamboo provides timbers that are tubular and cylindrical in shape, which is readily adaptable for use as the structural vertical poles 11 and rods 10 for our invention. Local people in third world countries can readily source these natural bamboo poles and adapt them into the vertical poles and rods of our invention. Therefore, by using natural bamboo poles to constitute the structural supporting components of our balance of part, we are creating an invention that is greener, more environmentally friendly, and leave a much smaller carbon footprint into the atmosphere. There are other embodiments which can make the invention even greener, cleaner, and more environmentally friendly, and those skilled in the art will be able to devise such other embodiments.

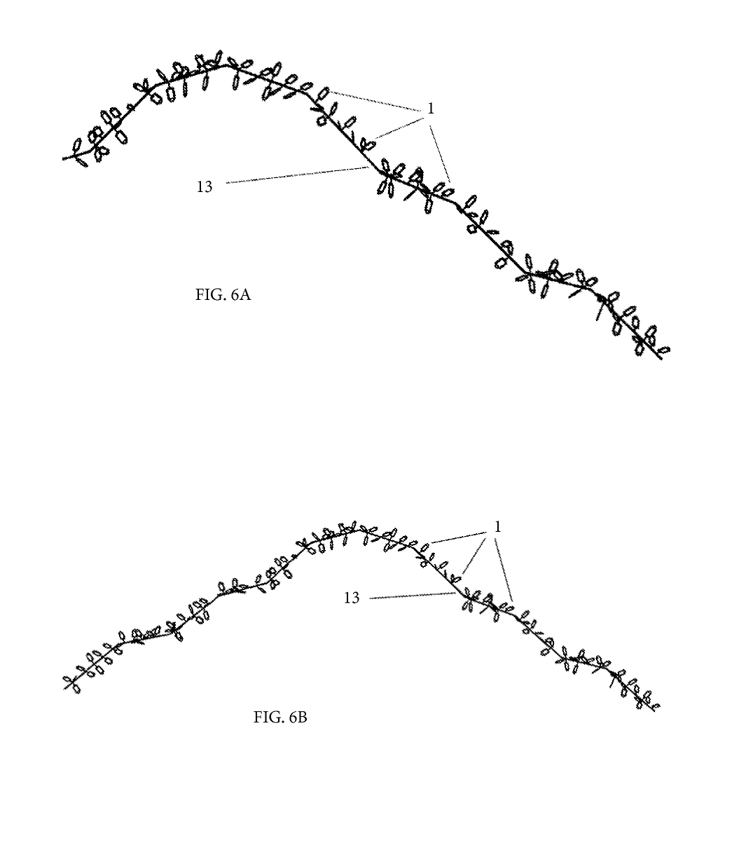

To illustrate the value of reducing the number of components in the balance of system, we illustrate another example of mounting our invention, the Photovoltaic solar leaf. In FIGS. 6A and 6B, we illustrate a method of mounting the PV solar leaf 1 along a flexible long electrical cord 13. The long electrical cord 13 is flexible, durable, and provides a platform for mounting the PV solar leaf. The long electrical cord 13 also serves to carry the electrical currents generated by the PV solar leaves 1. Those skilled in the art will be able to design various means by which the PV solar leaves are electrically and mechanically attached to the electrical cord. For example, the negative and positive electrical terminals from the PV solar leaf 1 are wired onto the negative and positive electrical wirings of the long electrical cord 13. The entire electrical wiring from the PV solar leaf to the long electrical cord is encapsulated in a flexible and strong electrical insulation material that is common and typical of electrical insulation in electrical power cords of common household appliances. The preferred material for the material to encapsulate and insulate the electrical wiring for the electrical cord 13 should be chosen to be corrosion resistant, durable, strong, and flexible, such as certain polymeric materials exhibiting both desirable mechanical properties and electrical insulation properties. Examples of corrosion resistant polymeric material are the polyolefins group of polymer and the polyvinyl chloride group of polymer. Specific examples include polyethylene, polypropylene, polyvinyl chloride (PVC), and chlorinated polyvinyl chloride (CPVC). There are many other examples of polymer that can be used, and those skilled in the arts will be able to choose other types of polymer as well as add the appropriate additives to the polymer resin during injection molding to provide structurally sound electrical insulation material with various desirable properties.

In this particular embodiment shown in FIGS. 6A and 6B, our invention can be mounted anywhere simply by wrapping the long electrical cord 13 around any structure and tying it into knots to secure it which would eliminate the needs for mechanical components such as screws, bolts, brackets and other components in the balance of system to secure it. By reducing the number of components in the balance of system to secure it, our invention provides an enormous utility in ease of mounting, reduction in cost and time required to mount it, and versatility in being able to be adapted to any environment and terrain conditions. For example, this embodiment can be mounted around large boulders by simply wrapping the electrical cord 13 around the boulders. The PV solar leaves along the long electrical cord 13 will be able to absorb sunlight from above as well as reflected sunlight from the surface of the boulder. It can also be mounted on poles by simply wrapping the electrical cord 13 around the vertical poles. It can also be hung between two poles a distance apart by tying the electrical cord 13 around the two poles. It can also be mounted onto any rooftop by simply wrapping the electrical cord 13 back and forth along the surface of the rooftop. Another major advantage of this embodiment is the ease of transporting and storing it. It can simply be rolled up into a small volume and easily transported to another location to be mounted. We envisage that our invention in this particular embodiment will provide great utility to poor family in third world countries because our invention will be sufficiently versatile, flexible, and durable to withstand the harsh environmental conditions found in any terrain on Earth in order to generate much needed electricity from solar energy.

Cost of production, ease of mounting the array, and portability are very important factors for any solar PV system to be widely utilized. The prior art's solar PV system suffer from major disadvantages of being too heavy, bulky, expensive, and difficult to transport and mount. The prior art's balance of system components requires to mount a solar PV system are enormous in number, which increase the cost of utilizing such PV system. Thus, if we can reduce the number of components in the balance of system, we can reduce the cost of the PV system. Our PV solar leaf module is the simplest module that can be created. It comprises simply of a very thin film of active PV layer supported by 2 sheets of light trapping polymer. In this simple form, the PV solar leaf module is light weight, flexible, and durable, making unnecessary the use of all the components in the balance of system. As the active thin film PV layer is made thinner, its cost of production will decrease. Together, these cost savings in our PV solar leaf module will make it possible for third world countries to utilize our PV solar leaf module for generating electricity from sunlight because our invention will make it economically affordable enough such that every poor family in third world countries will be able to own one to generate much needed electricity.

Having described the preferred embodiment of our invention above, we now turn to other potential embodiments of our invention that those skilled in the art will be readily able to create with minimal experimentation. While our preferred material for the active layer comprises of GaAs, there are also other possible Photovoltaic (PV) material that can be used as the active PV thin film layer. For example, Si can be used if the Si thin film can be made to be 500 nm or less in which case, it exhibit mechanical properties that are flexible. Other potential thin film PV materials are cadmium telluride (CdTe), copper indium gallium diselenide (CIGS), Titanium Dioxide (TiO2) nanowires, Indium Gallium Phosphide (InGaP) and other form of PV organic thin film material. As long as these thin film materials can be made to be 500 nm or less, they will all exhibit mechanical properties that are flexible and durable. These other candidate materials for the active PV thin film are less efficient than the GaAs thin film material, which is why we choose GaAs as our preferred material.

However, there is another potential class of PV material that may become extremely important as a candidate for our active thin film PV material, which is the graphene. Graphene is a monolayer of carbon atoms arranged in a hexagonal pattern in a 2 dimensional sheet. Graphene as an active photovoltaic (PV) thin film layer may have the potential to have 60% efficiency in converting photon into electron. Moreover, grapheme has the ability to convert one photon into multiple electrons. However, grapheme suffered from many technical problems for present commercial application because it is still in the research and experimental stage. One of these problem is that graphene has very low absorption for sunlight. Here is where our invention can solve this problem. When graphene become technologically ready to be adopted as an active PV thin film layer for our invention, the PV solar leaf module, the encapsulation of the graphene PV active thin film layer between two light trapping polymer sheets on both surfaces of the graphene will trap sunlight and redirect the sunlight back onto the active grapheme PV layer. Those skilled in the art will be able to adopt our invention, the PV solar leaf module to incorporate the graphene active PV thin film layer in the future. It is hoped that our invention, a new type of photovoltaic module, the PV solar leaf module, will improve, enhance, and evolve the technology of solar photovoltaic electrical generation to the point where solar generated electricity will become widely available for everybody in the world.

We claim a dual surface sunlight trapping photovoltaic solar leaf module comprising of:

1. An active photovoltaic (PV) thin film layer sandwiched between two sheets of light trapping surface textured polymers; with
said active PV thin film layer less than 500 nm in thickness, which can be as thin as 100 nm, or as thin as 50 nm, or as thin as a few atomic layers; with
said active PV thin film layer comprising of a photovoltaic (PV) material capable of converting sunlight into electricity; with
said light trapping surface textured polymer being in optical contact with the front surface of said active PV thin film layer; with
another said light trapping surface textured polymer being in optical contact with the back surface of said active PV thin film layer; with
said light trapping surface textured polymer sheets redirecting sunlight onto the active PV thin film layer; with
said two sheets of light trapping polymer laminating the active PV thin film layer in between;
with the edges of said two laminated light trapping polymer sheets fused together to form an air-tight and water-tight protective casing around said active PV thin film layer;
with the properties that said PV solar leaf module being light weight, flexible, thin and durable;
with an electrical cord protruding from said laminated active thin film PV layer;
with the capability of absorbing and trapping sunlight on the front surface of said PV solar leaf module; as well as
the capability of absorbing and trapping sunlight on the back surface of said PV solar leaf module.

2. A method of mounting said PV solar leaf modules comprising of:
mounting an array of said PV solar leaf modules in various orientations and various angles along a rod; and
mounting said rods along a vertical pole in various orientations and various angles; with
said pole which is attached to and supported by a supporting base; with
said base being attached to a ground surface or embedded into the ground surface.

3. A method of mounting said PV solar leaf, comprising:
mounting many said PV solar leaves along a long flexible electrical cord;
mechanically attaching many said PV solar leaves onto said long flexible electrical cord;
electrically attaching many said PV solar leaves onto said long flexible electrical cord;
with said long flexible electrical cord being flexible, durable, strong, and resistant to corrosion;
with insulating material encapsulating the entire electrical wiring;
with insulating material comprising of corrosion resistant polymers, which provide properties such as corrosion resistance, mechanical strength, flexibility, durability, and electrical insulation.
